(19) United States
(12) Patent Application Publication
(10) Pub. No.: US 2026/0075956 A1
(43) Pub. Date: Mar. 12, 2026

(54) Electrostatic Discharge Protection Using Ovonic Threshold Switching

(71) Applicant: International Business Machines Corporation, Armonk, NY (US)

(72) Inventors: Masoud Zabihi, Schenectady, NY (US); Timothy Mathew Philip, Albany, NY (US); Robert Gauthier, Williston, VT (US); Juntao Li, Cohoes, NY (US); Anindya Nath, Watervliet, NY (US)

(21) Appl. No.: 18/882,960

(22) Filed: Sep. 12, 2024

(51) Int. Cl. H01L 27/02

(52) U.S. Cl. CPC H10D 89/611

(57) ABSTRACT

An electrostatic discharge (ESD) protection diode in a semiconductor integrated circuit (IC) includes a silicon wafer. The IC includes a well region within the silicon wafer. The IC includes an N+ region and a P+ region within the well region. The IC includes a gate dielectric layer on top of the silicon wafer. The IC includes a floating gate layer on top of the gate dielectric layer. The IC includes an ovonic threshold switching (OTS) layer on top of the floating gate layer. The IC includes an interlayer dielectric (ILD) on top of the OTS layer.

### BACKGROUND

The present disclosure relates generally to electrostatic discharge (ESD) protection in semiconductor integrated circuits (ICs), and more specifically to ESD protection in semiconductor ICs using ovonic threshold switching (OTS).

ESD protection is critical for ensuring the reliability and longevity of semiconductor ICs. ESD events, which can occur during manufacturing, assembly, operation or handling by end-users, can introduce high-voltage transients or spikes in ICs. These high voltage transients or spikes can penetrate thin oxide layers of transistors, causing irreversible damage to ICs.

Traditionally, ESD protection in ICs has been implemented using ESD protection diodes. These diodes are designed to clamp the voltage spikes by diverting ESD current away from sensitive internal circuitry to ground, thereby preventing damage to the IC components.

While ESD protection diodes mitigate the risks associated with ESD events, they have drawbacks in the context of semiconductor fabrication, where device miniaturization and performance optimization are crucial. ESD protection diodes occupy a considerable amount of silicon area in semiconductor ICs. As device dimensions shrink and the demand for higher integration increases, the silicon area available for ESD protection becomes a design constraint. The large area required for ESD protection diodes limits the ability to integrate additional functional circuitry, thereby impacting the overall functionality and cost-efficiency of ICs.

Also, ESD protection diodes exhibit high capacitance, which can adversely affect the performance of ICs. The large capacitance associated with these diodes leads to slower signal propagation, reduced operating speed, and degraded signal integrity. This is detrimental in high-speed and high-frequency applications, where maintaining signal integrity and minimizing delay are paramount.

Another drawback of ESD protection diodes is the presence of significant leakage current. The leakage current contributes to increased power consumption, which is undesirable in power-sensitive applications such as mobile wireless devices, laptop computers and other battery-operated devices.

Accordingly, there is a need for alternative ESD protection solutions that can provide effective protection without these drawbacks.

### SUMMARY

Illustrative embodiments provide an electrostatic discharge (ESD) protection diode in a semiconductor integrated circuit (IC). The ESD protection diode includes a silicon wafer and a gate dielectric layer on top of the silicon wafer. The ESD protection diode includes a floating gate layer on top of the gate dielectric layer and an ovonic threshold switching (OTS) layer on top of the floating gate layer. The ESD protection diode includes an interlayer dielectric (ILD) on top of the OTS layer. The ESD protection diode includes a first contact area (CA) within the ILD. The first CA provides a low-resistance connection between a first doped region within the silicon wafer and a first metal interconnect layer. The ESD protection diode includes a second contact area (CA) within the ILD. The second CA provides a low-resistance connection between a second doped region within the silicon wafer and a second metal interconnect layer. Another illustrative embodiment provides a semiconductor IC which includes an ESD protection diode configured to protect a functional circuit during an ESD event.

### BRIEF DESCRIPTION OF THE DRAWINGS

The novel features of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 illustrates a cross-sectional view of an electrostatic discharge (ESD) protection diode in a semiconductor IC in accordance with an illustrative embodiment;

FIG. 2A illustrates the IC of FIG. 1 in a normal operating condition;

FIG. 2B illustrates the IC of FIG. 1 in an ESD event;

FIG. 3A illustrates a semiconductor IC in accordance with another illustrative embodiment;

FIG. 3B illustrates an OTS device in accordance with an illustrative embodiment;

FIG. 4A illustrates the IC of FIG. 3A during a normal operating condition;

FIG. 4B illustrates the IC of FIG. 3A during an ESD event; and

FIG. 5 illustrates a semiconductor IC in accordance with another illustrative embodiment.

### DETAILED DESCRIPTION

The illustrative embodiments address limitations of existing electrostatic discharge (ESD) protection diodes in semiconductor integrated circuits (ICs). The illustrative embodiments provide ESD protection diodes which incorporate ovonic threshold switching (OTS) material. The illustrative embodiments occupy less silicon area in ICs, exhibit low capacitance and low leakage current.

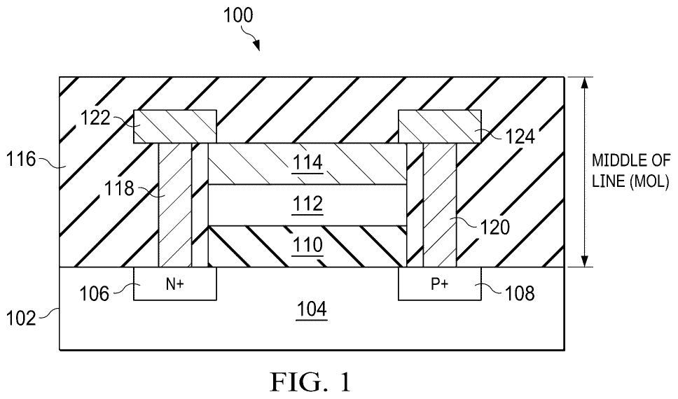

FIG. 1 illustrates a cross-sectional view of an ESD protection diode in a semiconductor IC 100 in accordance with an illustrative embodiment. IC 100 includes silicon wafer 102, which serves as the foundation for building electronic devices (e.g., diodes, transistors). IC 100 includes well 104 within silicon wafer 102. In some embodiments, well 104 is a P-well which is formed by doping silicon wafer 102 with acceptor impurities (e.g., boron). In other embodiments, well 104 is an N-well which is formed by doping silicon wafer 102 with donor impurities (e.g., phosphorus). Well 104 serves as the base for forming the ESD protection diode structure.

IC 100 includes first doped region 106 and second doped region 108 which are formed within well 104. In some embodiments, first doped region 106 is an N+ region (n-type region) and second doped region 108 is a P+ region (p-type region). In other embodiments, first doped region is a P+ region and second doped region 108 is an N+ region.

IC 100 includes gate dielectric layer 110 on top of silicon wafer 102. In an illustrative embodiment, gate dielectric layer 110 can be formed with silicon nitride (SiN) or silicon dioxide (SiO₂) using thermal oxidation, where silicon wafer 102 is exposed to oxygen at high temperatures, or through chemical vapor deposition (CVD). Gate dielectric layer 110 can also be formed using a high-k dielectric material (e.g., HfO2). Gate dielectric layer 110 acts as an insulating layer for electronic devices (e.g., diodes).

IC 100 includes gate layer 112 on top of gate dielectric layer 112. Gate layer 112 (also referred herein as a floating gate layer) is a conductive layer formed on top of gate dielectric layer 110. In some embodiments, gate layer 112 is formed using high-k metal or polysilicon. Gate layer 112 acts as a gate electrode in the diode structure and modulates the conductivity of the channel formed between the N+ and P+ regions in the underlying silicon.

IC 100 includes OTS layer 114 on top of gate dielectric layer 112. OTS layer 114 is formed with a chalcogenide material such as, for example, tellurium (Te), sulfur (S), selenium (Se) or other amorphous materials.

In an illustrative embodiment, IC 100 includes interlayer dielectric (ILD) 116 on top of OTS layer 114 and over exposed areas of silicon wafer 102 ILD 116 can be formed by depositing silicon dioxide or a low-k dielectric material using techniques such as CVD or spin coating. ILD 116 insulates different parts of circuits and serves as a base for interconnects. In some embodiments, IC 100 may include multiple levels of ILDs.

IC 100 includes contact areas (CAs) 118 and 120 which are formed using a conductive material (e.g., copper or tungsten). In an illustrative embodiment, CAs 118 and 120 are formed by filling vias which are small holes etched through ILD 116 to connect the underlying first and second doped regions. CA 118 creates a low-resistance connection between first doped region 106 and metal interconnects that carry signals across the IC. CA 120 creates a low-resistance connection between second doped region 108 and the metal interconnects that carry signals across the IC.

IC 100 includes metal 1 (M1) layers 122 and 124 on top of respective CAs 118 and 120. M1 layers 122 and 124 are formed by depositing copper or aluminum on top of CAs 118 and 120. M1 layers 122 and 124 are the first layers of metal interconnects deposited on top of CAs 118 and 120.

In the illustrative embodiment, M1 layer 124 serves as the anode terminal of the ESD protection diode and M1 layer 122 serves as the cathode terminal of the ESD protection diode. M1 layers 122 and 124 provide the primary routing for electrical signals within IC 100 and connect various components, such as diodes, transistors, capacitors, and resistors, within IC 100 to form functional circuits.

In one aspect, IC 100 is an ESD protection diode which has a floating gate configuration and an overlaying OTS layer. A floating gate refers to a gate that is electrically isolated and does not have a direct connection to a control terminal. The floating gate can hold a charge, influencing the behavior of the surrounding regions without being directly controlled by an external voltage. In IC 100, gate layer 112 is floating because it is not directly connected to M1 layers 122 and 124. Thus, gate layer 112 is electrically isolated from M1 layers 122 and 124. Although gate layer 112 is not electrically connected to electrodes or external terminals, gate layer 112 is influenced by the surrounding electric fields, induced by OTS layer 114 when an ESD event occurs.

A notable property of OTS layer 114 is that under normal operating conditions, OTS layer 114 remains in a high resistance state and does not conduct significant current. However, when the voltage across OTS layer 114 exceeds a threshold voltage Vₜₕ, OTS layer 114 switches to a highly conductive state, allowing current to flow easily. The switch is reversible. As the voltage across OTS layer 114 drops below the threshold Vₜₕ, OTS layer 114 returns to its original insulating state.

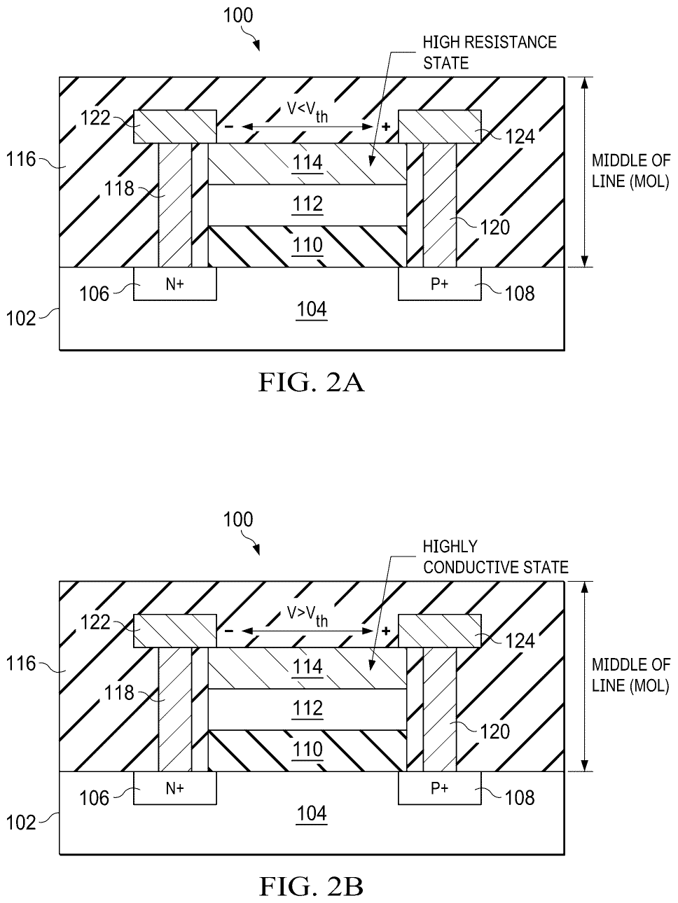

In the illustrative embodiment, the characteristics of OTS layer 114 are utilized to improve the performance of the ESD protection diode within IC 100. Under normal operating conditions as shown in FIG. 2A, the voltage across OTS layer 114 is below the threshold Vth. So, OTS layer 114 remains in a high-resistance state and does not conduct significant current. When an ESD event occurs causing a voltage transient or spike within IC 100 as shown in FIG. 2B, the voltage across OTS layer 114 exceeds the threshold Vth. As such, OTS layer 114 switches to a highly conductive state, allowing an overcurrent (e.g., excess current) to pass through OTS layer 114 rather than the sensitive parts of IC 100. The switching from the high resistance state to the highly conductive state happens rapidly, which is critical for protecting IC 100 against fast transient events like ESD. Also, the ability of OTS layer 114 to switch back to the high resistance state means that the protection mechanism can be used repeatedly without degradation.

Incorporating OTS layer 114 into IC 100 significantly enhances the ESD protection diode's ability to protect IC 100 against voltage transients and spikes. During an ESD event, OTS layer 114 helps to control the flow of current between second doped region 108 and first doped region 106 through silicon wafer 102. When placed over gate layer 112, OTS layer 114 creates a floating gate configuration which enhances the ESD protection diode's ability to manage and distribute the energy associated with an ESD event. The floating gate can modulate the electric field distribution between the P+ region and the N+ region within the ESD protection diode, improving its ability to withstand high voltage spikes and further protecting IC 100. The presence of OTS layer 114 improves the ESD protection diode's clamping efficiency. By rapidly switching states in response to a voltage spike, OTS layer 114 ensures that the ESD protection diode clamps the voltage at a safer, lower level, thereby protecting IC 100 from being exposed to harmful voltage levels.

In the illustrative embodiment, the layers above silicon wafer 104 can be considered as the middle of line (MOL) area of IC 100. Because gate dielectric layer 110, gate layer 112, OTS layer 114, CAs 118 and 120 and M1 layers 122 and 124 are formed in the MOL area, the ESD protection diode does not occupy a large area in the silicon area in IC 100. As such, more silicon area in IC 100 remains available for integrating functional circuitry, thereby improving the overall functionality and cost-efficiency of IC 100.

Furthermore, the ESD protection diode in IC 100 can be designed with intrinsically low capacitance because the OTS layer 114 does not require a large junction area to function effectively. The low capacitance ensures that the ESD protection diode has minimal impact on the signal integrity of high-speed circuits. Also, the high resistance state of OTS layer 114 in its “off” state results in very low leakage current. This is advantageous in reducing power consumption in ICs.

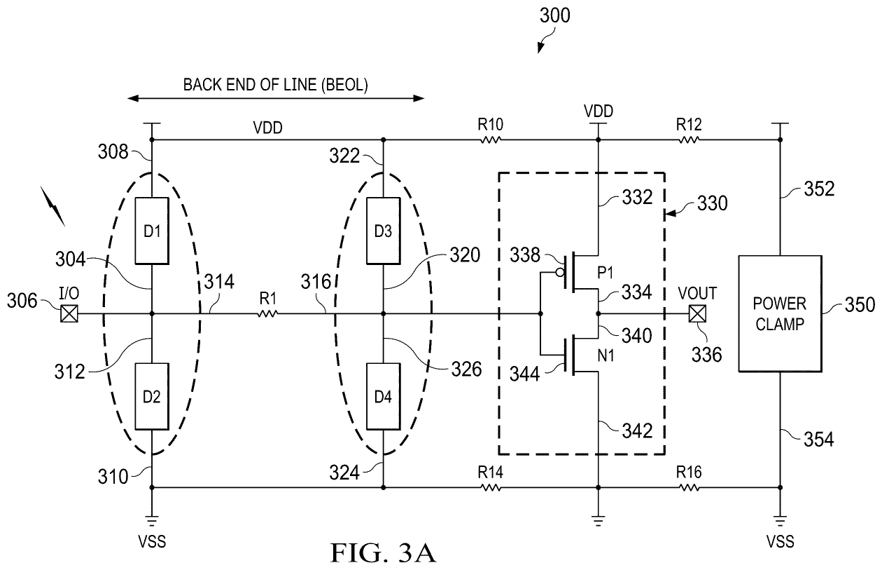

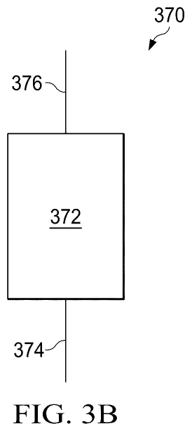

FIG. 3A illustrates semiconductor IC 300 in accordance with another illustrative embodiment. IC 300 includes multiple ovonic threshold switching (OTS) devices configured to protect a functional circuit in an ESD event.

IC 300 includes OTS device D1 which has terminal 304 (e.g., anode) connected to input/output (I/O) terminal 306 (also referred to as circuit input) and has terminal 308 (e.g., cathode) connected to voltage supply VDD (e.g., 500 mV or 1.5V). IC 300 includes OTS device D2 which has terminal 310 (e.g., anode) connected to reference voltage VSS (e.g., ground) and has terminal 312 (e.g., cathode) connected to I/O terminal 306. IC 300 includes resistor R1 (e.g., 10K) which has terminal 314 connected to I/O terminal 306 and has terminal 316. IC 300 includes OTS device D3 which has terminal 320 (e.g., anode) connected to terminal 316 of R1 and has terminal 322 (e.g., cathode) connected to voltage supply VDD. IC 300 includes OTS device D4 which has terminal 324 (e.g., anode) connected to reference voltage VSS and has terminal 326 (e.g., cathode) connected to terminal 316 of R1.

In an example embodiment, OTS devices D1-D4 can be implemented as the ESD protection diode illustrated in FIGS. 1 and 2A-2B. In other example embodiments, OTS devices D1-D4 are two-terminal OTS devices such as OTS device 370 illustrated in FIG. 3B. OTS device 370 includes OTS material 372 connected to anode 374 and cathode 376.

In some example embodiments, IC 300 includes only two OTS devices. For example, the IC can be fabricated with only OTS devices D3 and D4.

IC 300 includes inverter 330 which is also referred herein as a first circuit or a victim device. In other embodiments, the first circuit or the victim device can be any functional circuit. In the illustrative embodiment, OTS devices D1-D4 are designed to protect the victim device during an ESD event.

Inverter 300 includes PMOS transistor P1 which has source 332 connected to voltage supply VDD and has drain 334 connected to output terminal 336 (e.g., circuit output). PMOS transistor P1 has gate 338 connected to terminal 316 of R1. Inverter 300 includes NMOS transistor N1 which has drain 340 connected to output terminal 336 and has source 342 connected to reference voltage VSS. NMOS transistor N1 has gate 344 connected to terminal 316 of R1. Thus, gate 338 of P1 is connected to gate 344 of N1 and drain 334 of P1 is connected to source 342 of N1. The interconnection node of gates 338 and 344 is referred to as an input of the first circuit (e.g., inverter 330) and the interconnection node of drain 334 and source 342 is referred to as an output of the first circuit.

IC 300 includes power clamp circuit 350 coupled between voltage supply VDD and reference voltage VSS (e.g., ground). Power clamp circuit 350 has first terminal 352 connected to voltage supply VDD and has second terminal 354 connected to reference voltage VSS. Power clamp circuit 350 regulates and limits the voltage between voltage supply VDD and reference voltage VSS (e.g., ground) to prevent damage to the circuit components. During an ESD event, power clamp circuit 350 clamps the voltage by allowing overcurrent to flow to ground, thereby protecting inverter 330 from high-voltage transients. Power clamp circuit 350 can be implemented, for example, as a Zener diode, a transient voltage suppression (TVS) diode or a transistor-based clamp circuit.

IC 300 includes resistors R10 and R12 which represent equivalent resistances of a power rail (e.g., conductor) which provides voltage supply VDD. IC 300 includes resistors R14 and R16 which represent equivalent resistances of a ground rail which provides the reference voltage VSS. In some example embodiments, the total resistance of R10, R12, R14 and R16 is around 0.5 ohms.

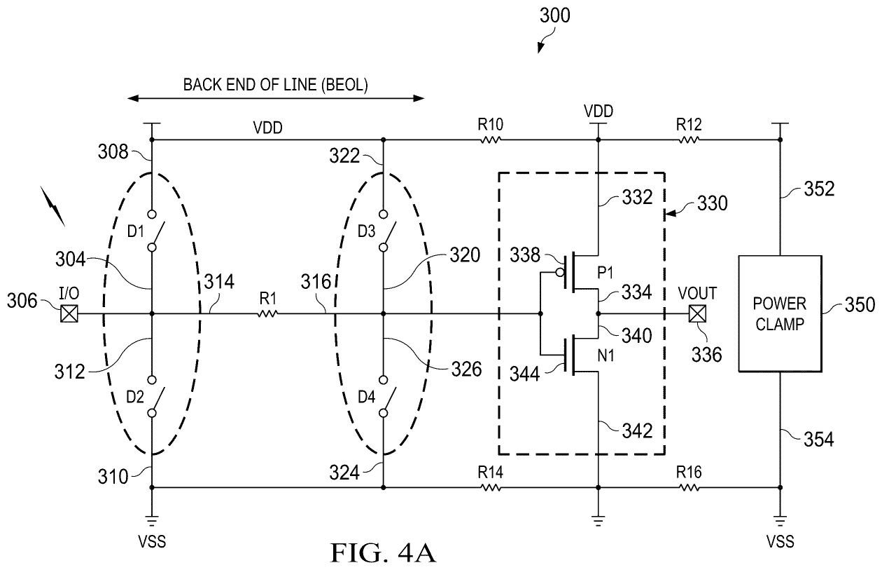

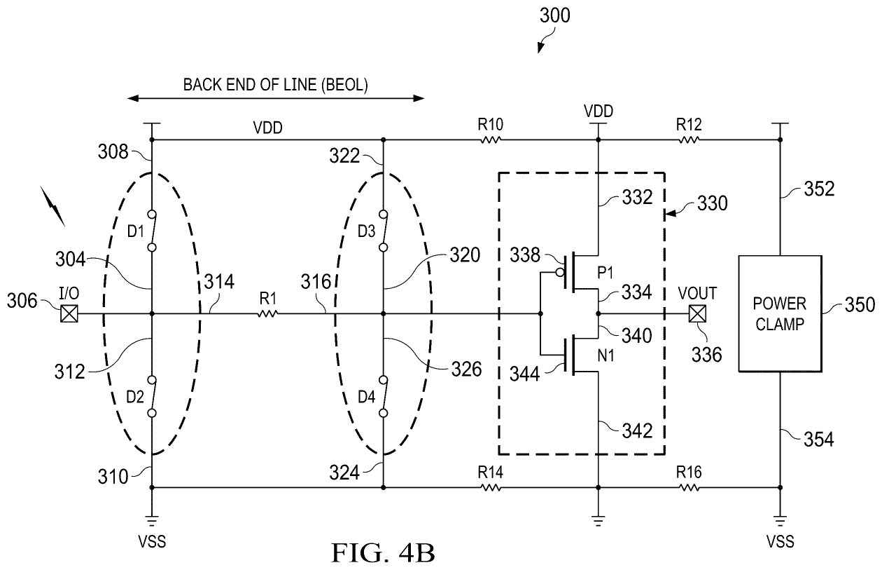

During normal operation which is illustrated in FIG. 4A, IC 300 receives I/O signal at I/O terminal 306 and in response provides output signal Vout at output terminal 336 (also referred to as circuit output). Because I/O signal level is below the threshold voltage Vₜₕ, OTS devices D1-D4, D1-D4 remain in high resistance states and do not conduct significant current. In FIG. 4A, OTS devices D1-D4 are shown as open circuits (or open switches) to indicate they conduct insignificant current. As such, OTS devices D1-D4 do not interfere with normal operation of IC 300.

When I/O signal is HIGH (e.g., 150 mV or 250 mV), PMOS transistor P1 is turned OFF but NMOS transistor N1 is turned ON. Thus, NMOS transistor N1 conducts, thereby coupling output terminal 336 to reference voltage VSS (e.g., ground), which causes output signal Vout to become LOW. When I/O signal is LOW (e.g., 0V), PMOS transistor P1 is turned ON but NMOS transistor N1 is turned OFF. Thus, PMOS transistor P1 conducts, thereby coupling output terminal 336 to voltage supply VDD, which causes output signal Vout to become HIGH.

In an ESD event (e.g., voltage transient or spike), the voltage at I/O terminal 306 can surge to a very high level causing an overcurrent to flow through I/O terminal 306. Typically, ESD events are brief (e.g., between 1 to 100 nanoseconds) but can reach extremely high voltages, exceeding several kilovolts. Because the voltage at I/O terminal 306 surges much higher than the threshold voltage Vth, OTS devices D1 and D3 switch to highly conductive states as illustrated in FIG. 4B, thus allowing the overcurrent to flow through D1 and D3. In FIG. 4B, the OTS devices are shown as closed switches to indicate high conductive states which allow current to easily flow through. The voltage spike causes VDD to exceed the predetermined threshold of power clamp circuit 350. Thus, power clamp circuit 350 turns ON, allowing the overcurrent to flow through power clamp circuit 350 to ground. Because the overcurrent flows through OTS devices D1, D3 and then through power clamp circuit 350, the overcurrent is diverted away from inverter 330, thus protecting inverter 330. The high resistance value of resistor R1 (e.g., 10 kohms) also limits the overcurrent flowing through IC 300 in an ESD event. If the voltage spike is around 5 kV, resistor R1 limits the overcurrent to around 500 mA.

Also, the ESD event causes OTS devices D2 and D4 to switch to highly conductive states. As such, gate terminal 338 of transistor P1 and gate terminal 344 of transistor N1 are rapidly pulled to ground, thereby protecting transistors P1 and N1 from the overcurrent. After the ESD event, the voltages across OTS devices D1-D4 drop below the threshold Vₜₕ, and as a result OTS devices D1-D4 return to their original insulating states.

In an example embodiment, OTS devices D1-D4 are formed in the back end of line (BEOL) area of IC 300. As such, IC 300 provides ESD protection without occupying large area in the silicon area in IC 300. Thus, more silicon area in IC 300 is available for integrating functional circuitry, thereby improving the overall functionality and cost-efficiency of IC 300.

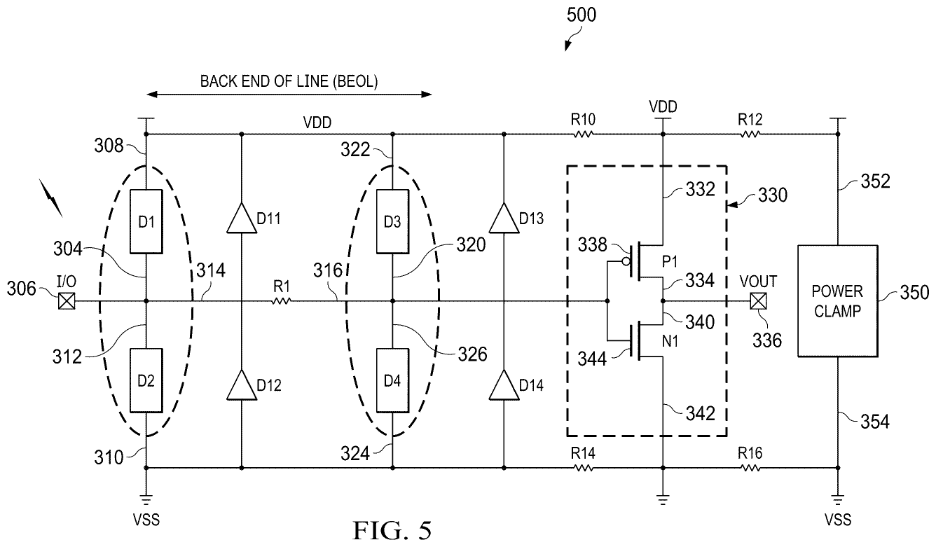

FIG. 5 illustrates semiconductor IC 500 in accordance with another illustrative embodiment. IC 500 includes OTS devices D1, D2, D3 and D4 configured to protect a functional circuit in an ESD event. IC 500 also includes conventional diodes D11, D12, D13 and D14 coupled in parallel to respective OTS devices D1, D2, D3 and D4. In all other aspects, IC 500 is similar to IC 300. In an ESD event, conventional diodes D11, D12, D13 and D14 provide additional paths for the overcurrent to flow through, and thus provide enhanced protection to IC 500 against voltage spikes. In an illustrative embodiment, OTS devices D1-D4 and conventional diodes D11-D14 are fabricated in the back end of line (BEOL) region of IC 500. The BEOL region primarily includes interconnect layers that connect active devices such as transistors, capacitors, and other components in IC 500, allowing them to function together as a complete circuit.

As used herein, “a number of,” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The different illustrative examples describe components that perform actions or operations. In an illustrative embodiment, a component may be configured to perform the action or operation described. For example, the component may have a configuration or design for a structure that provides the component an ability to perform the action or operation that is described in the illustrative examples as being performed by the component.

Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. An electrostatic discharge (ESD) protection diode in a semiconductor integrated circuit (IC), comprising:
a silicon wafer;
a gate dielectric layer on top of the silicon wafer;
a floating gate layer on top of the gate dielectric layer;
an ovonic threshold switching (OTS) layer on top of the floating gate layer; and
an interlayer dielectric (ILD) on top of the OTS layer.

2. The ESD protection diode of claim 1, wherein the OTS layer is formed within a middle of line (MOL) region of the semiconductor IC.

3. The ESD protection diode of claim 1, further comprising:
a first contact area (CA) within the ILD, the first CA providing a low-resistance connection between a first doped region within the silicon wafer and a first metal interconnect layer; and
a second contact area (CA) within the ILD, the second CA providing a low-resistance connection between a second doped region within the silicon wafer and a second metal interconnect layer.

4. The ESD protection diode of claim 3, wherein the floating gate layer is electrically isolated from the first and second metal interconnect layers.

5. The ESD protection diode of claim 1, wherein the OTS layer is formed with tellurium (Te), sulfur(S), selenium (Se), or a chalcogenide material.

6. The ESD protection diode of claim 1, wherein the ILD is formed with silicon dioxide or a low-k dielectric material.

7. The ESD protection diode of claim 1, wherein the first and second CAs are formed with copper or tungsten.

8. An electrostatic discharge (ESD) protection diode in a semiconductor integrated circuit (IC), comprising:
a silicon wafer;
a first and a second doped region formed within the silicon wafer;
a gate dielectric layer on top of the silicon wafer;
a floating gate layer on top of the gate dielectric layer;
an ovonic threshold switching (OTS) layer on top of the floating gate layer;
an interlayer dielectric (ILD) on top of the OTS layer and exposed areas of the silicon wafer;
a first contact area (CA) creating a low-resistance connection between the first doped region and a first metal interconnect layer; and
a second contact area (CA) creating a low-resistance connection between the second doped region and a second metal interconnect layer,
wherein the floating gate layer is electrically isolated from the first and second metal interconnect layers.

9. The ESD protection diode of claim 8, wherein the OTS layer is formed within a middle of line (MOL) region of the semiconductor IC.

10. The ESD protection diode of claim 8, wherein the OTS layer is formed with tellurium (Te), sulfur(S), selenium (Se), or a chalcogenide material.

11. The ESD protection diode of claim 8, wherein the first doped region is an N+ region and the second doped region is a P+ region.

12. The ESD protection diode of claim 8, wherein the first doped region is a P+ region and the second doped region is an N+ region.

13. A semiconductor integrated circuit (IC) comprising:
a circuit input;
a circuit output;
a resistor having a first terminal connected to the circuit input and having a second terminal;
a first ovonic threshold switching (OTS) device having a first terminal connected to the second terminal of the resistor and a second terminal connected to a voltage supply;
a second OTS device having a first terminal connected to a reference voltage and a second terminal connected to the second terminal of the resistor;
a first circuit coupled between the voltage supply and the reference voltage, the first circuit having an input coupled to the second terminal of the resistor and having an output connected to the circuit output; and
a power clamp circuit coupled between the voltage supply and the reference voltage.

14. The semiconductor IC of claim 13, further comprising:
a third OTS device having a first terminal connected to the circuit input and a second terminal connected to the voltage supply; and
a fourth OTS device having a first terminal connected to the reference voltage and a second terminal connected to the circuit input.

15. The semiconductor IC of claim 13, wherein the first and second OTS devices are fabricated in a back end of line (BEOL) area of the IC.

16. The semiconductor IC of claim 13, wherein the third and fourth OTS devices are fabricated in a back end of line (BEOL) area of the IC.

17. The semiconductor IC of claim 13, wherein the first and second OTS devices have high resistance states if a voltage across each of the first and second OTS devices is below a threshold voltage.

18. The semiconductor IC of claim 13, wherein the first and second OTS devices have highly conductive states if a voltage across each of the first and second OTS devices exceeds a threshold voltage.

19. The semiconductor IC of claim 13, wherein the power clamp circuit is configured to allow an overcurrent to flow through to the reference voltage during an electrostatic discharge (ESD) event.

20. The semiconductor IC of claim 13, wherein the first and second OTS devices have highly conductive states during an electrostatic discharge (ESD) event, thereby diverting an overcurrent away from the first circuit.
